(19) United States
(12) Patent Application Publication
(10) Pub. No.: US 2019/0049482 A1
(43) Pub. Date: Feb. 14, 2019

(54) DIFFERENTIAL Z-AXIS RESONANT MEMS ACCELEROMETERS AND RELATED METHODS

(71) Applicant: Analog Devices, Inc., Norwood, MA (US)

(72) Inventor: Mehrnaz Motiee, Cambridge, MA (US)

(73) Assignee: Analog Devices, Inc., Norwood, MA (US)

(21) Appl. No.: 15/674,410

(22) Filed: Aug. 10, 2017

(51) Int. Cl. G01P 15/125; G01P 15/18

(52) U.S. Cl. CPC G01P 15/125; G01P 15/18; B81B 2201/0235; B81B 2203/04; B81B 2203/0307

(57) ABSTRACT

A MEMS resonant accelerometer is described. The MEMS resonant accelerometer may comprise a pair of proof masses configured to resonate when driven with periodic signals. In this respect, the accelerometer's proof masses may serve as masses for detecting accelerations as well as resonators. The MEMS resonant accelerometer may comprise drive electrodes for causing the proof masses to resonate and sense electrodes for sensing motion of the proof masses. The magnitude of a z-axis acceleration, that is, an acceleration perpendicular to the plane of the proof masses, may be detected by sensing the frequency at which the proof masses resonate in the presence of such an acceleration. The proof masses may be arranged to produce differential signals.

### FIELD OF THE DISCLOSURE

The present application relates to microelectromechanical systems (MEMS) resonant accelerometers.

### BACKGROUND

Some MEMS accelerometers include a proof mass configured to move in response to acceleration. The extent to which the proof mass moves provides an indication as to the magnitude of the acceleration. Some MEMS accelerometers use capacitive sensors to detect the amplitude of the proof mass' motion.

### SUMMARY OF THE DISCLOSURE

According to one aspect of the present application, a microelectromechanical system (MEMS) resonant accelerometer is described. The MEMS resonant accelerometer may comprise a first teeter-totter proof mass coupled to a substrate through a first anchor at a first anchor location, the first teeter-totter proof mass having first and second mass portions disposed on opposite sides of the first anchor location, wherein the first mass portion is heavier than the second mass portion, a second teeter-totter proof mass coupled to the substrate through a second anchor at a second anchor location, the second teeter-totter proof mass having first and second mass portions disposed on opposite sides of the second anchor location, wherein the first mass portion is heavier than the second mass portion, a first sense electrode and a first drive electrode disposed between a common mass portion of the first teeter-totter proof mass and the substrate, and a second sense electrode and a second drive electrode disposed between a common mass portion of the second teeter-totter proof mass and the substrate.

According to another aspect of the present application, a microelectromechanical system (MEMS) resonant accelerometer is provided. The MEMS resonant accelerometer may comprise a pair of teeter-totter proof masses coupled to a substrate via respective anchors, each one of the anchors being offset with respect to a center of mass of the respective teeter-totter proof mass, wherein each of the anchors separates the respective teeter-totter proof mass into a first mass portion and a second mass portion, wherein the first mass portion is heavier than the second mass portion, a first sense electrode and a first drive electrode disposed between the first mass portion of a first teeter-totter proof mass of the pair of teeter-totter proof masses and the substrate, and a second sense electrode and a second drive electrode disposed between the second mass portion of a second teeter-totter proof mass of the pair of teeter-totter proof masses and the substrate.

According to yet another aspect of the present application, a method for sensing accelerations using a MEMS resonant accelerometer is provided. The method may comprise causing a first teeter-totter proof mass coupled to a substrate via a first anchor disposed at a first anchor location offset from a center of mass of the first teeter-totter proof mass and comprising first and second mass portions disposed on opposite sides of the first anchor location to resonate out-of-plane by applying a first drive signal to a first drive electrode disposed between a first mass portion of the first teeter-totter proof mass and the substrate, causing a second teeter-totter proof mass coupled to the substrate via a second anchor disposed at a second anchor location offset from a center of mass of the second teeter-totter proof mass and comprising first and second mass portions disposed on opposite sides of the second anchor location to resonate out-of-plane by applying a second drive signal to a second drive electrode disposed between a second mass portion of the second teeter-totter proof mass and the substrate, sensing motion of the first teeter-totter proof mass by sensing a first sense signal produced by a first sense electrode disposed between the first mass portion of the first teeter-totter proof mass and the substrate, and sensing motion of the second teeter-totter proof mass by sensing a second sense signal produced by a second sense electrode disposed between the second mass portion of the second teeter-totter proof mass and the substrate.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1A is a schematic top view illustrating a MEMS resonant accelerometer, according to some non-limiting embodiments.

FIG. 1B is a schematic top view illustrating a plurality of tethers as may be used with a MEMS resonant accelerometer, according to some non-limiting embodiments.

FIGS. 1C-1F are side views of the MEMS resonant accelerometer of FIG. 1A, according to some non-limiting embodiments.

FIG. 2A is a schematic top view illustrating a MEMS resonant accelerometer, according to an alternative non-limiting embodiment.

FIG. 2B is a cross sectional view of the MEMS resonant accelerometer of FIG. 2A, according to some non-limiting embodiments.

FIG. 3 is a block diagram illustrating circuitry for driving a MEMS resonant accelerometer, according to some non-limiting embodiments.

FIG. 4 is a block diagram illustrating a representative system comprising a MEMS resonant accelerometer, according to some non-limiting embodiments.

FIG. 5 is a schematic diagram illustrating a system comprising a MEMS resonant accelerometer connected to a person's body, according to some non-limiting embodiments.

### DETAILED DESCRIPTION

Applicant has appreciated that the sensitivity of MEMS resonant accelerometers to out-of-plane accelerations may be improved by combining the accelerometer's proof mass and the resonator into a single mass. MEMS resonant accelerometers are active accelerometers that are driven to resonate at a certain frequency. When the MEMS accelerometer experiences an acceleration, a frequency shift arises with respect to the frequency of the driving signal. The magnitude of the acceleration can be inferred from the frequency shift.

Some MEMS resonant accelerometers include a resonator that oscillates when driven, and a proof mass that moves in response to acceleration. The resonator and the proof mass are formed using separate masses, which allows MEMS designers to independently optimize the design of the two. Applicant has appreciated, however, that having separate masses may undesirably cause the MEMS resonant accelerometer to be overly sensitive to noise (e.g., Brownian noise), due to the presence of the additional mass.

Thus, some embodiments of the present application are directed to MEMS resonant accelerometers in which the resonator and the proof mass share, or are formed of, a single mass (or body). Such a single mass resonates when driven with a driving signal, and is allowed to move in response to accelerations. The frequency at which the single mass oscillates in response to acceleration may be detected using suitable detectors, thus providing a measure of the magnitude of the acceleration. Furthermore, some embodiments are directed to MEMS resonant accelerometers configured to operate differentially, in which a pair of masses is provided, with each of the masses being used as a resonator and a proof mass.

Single mass MEMS resonant accelerometers of the types described herein may be particularly advantageous when used in connection with MEMS processes having small proof mass/substrate separations (e.g., less than 1 μm). In these cases, the sensitivity to acceleration of conventional MEMS resonant accelerometers is substantially impaired, since the sensitivity of such devices decreases with the separation of the proof mass from the substrate. Nonetheless, the separation between the proof mass and the substrate is often a fixed parameter that is dictated by the MEMS fabrication process being used. As such, MEMS designers are often constrained to use the separation provided by the fabrication process, even if such a separation does not suit their needs. Detecting acceleration by using single mass MEMS resonant accelerometers of the types described herein may improve sensitivity to acceleration in spite of the small proof mass/substrate separation. This is due to the fact that, compared to conventional designs, the MEMS resonant accelerometers of the types described herein are less sensitive to noise.

Applicant has further appreciated that MEMS resonant accelerometers having separate masses for the proof mass and for the resonator may occupy a substantial amount of space on a substrate. By combining the proof mass and the resonator as described herein, the space occupied by the accelerometer may be decreased, thus freeing space for other components on the same substrate.

The aspects and embodiments described above, as well as additional aspects and embodiments, are described further below. These aspects and/or embodiments may be used individually, all together, or in any combination of two or more, as the application is not limited in this respect.

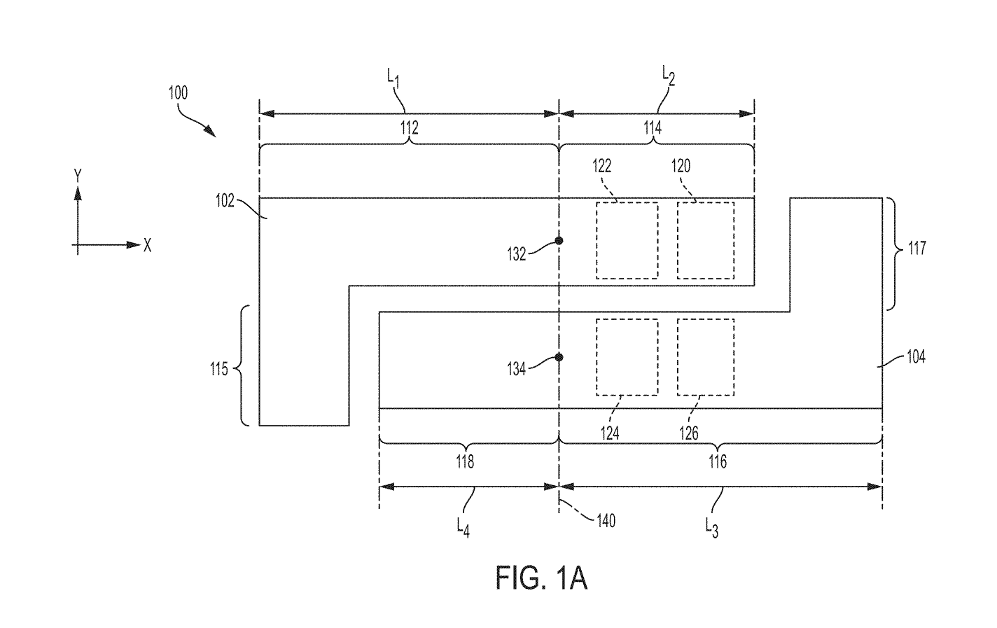

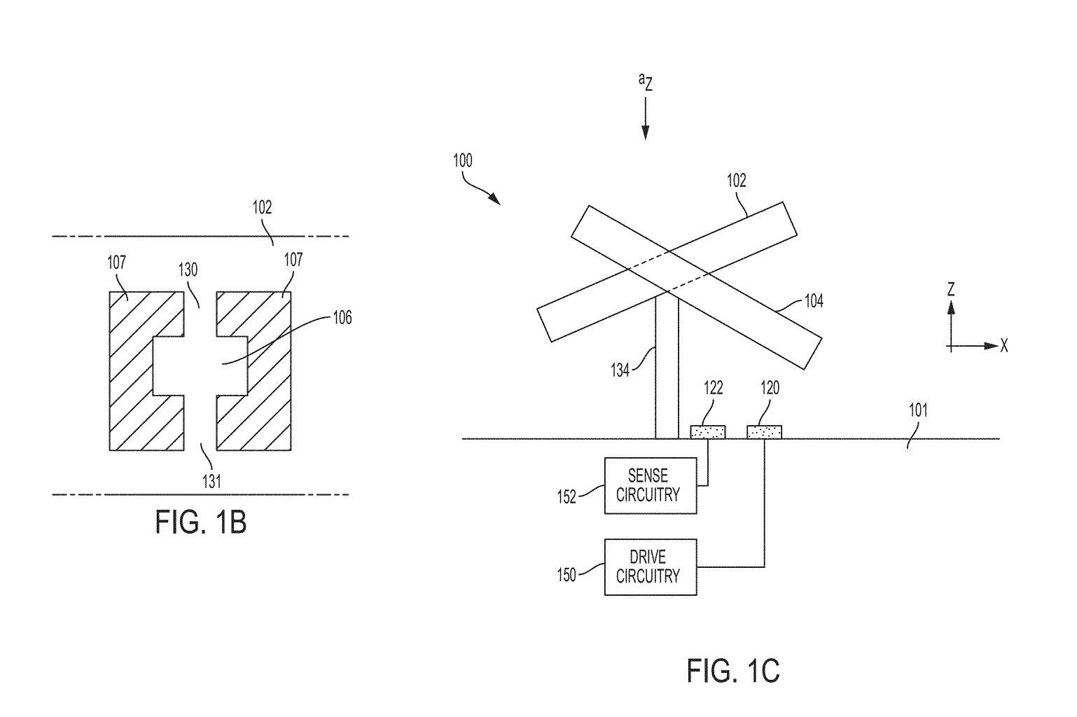

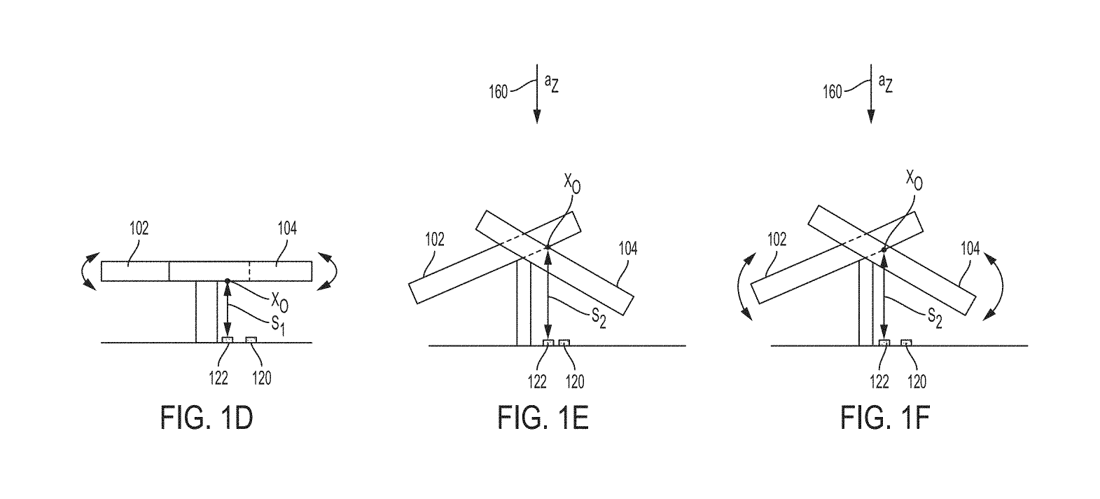

FIG. 1A is a top view schematic diagram illustrating a MEMS resonant accelerometer, according to some non-limiting embodiments. MEMS resonant accelerometer 100 comprises proof masses 102 and 104 (also referred to herein as resonators 102 and 104), sense electrodes 122 and 124, and drive electrodes 120 and 126. Sense electrodes 122 and 124, and drive electrodes 120 and 126 are shown in dashed lines to indicate that they are disposed on a different xy-plane than proof masses 102 and 104, as described in further detail below. MEMS resonant accelerometer 100 may be configured to detect accelerations that are perpendicular to the plane of the proof masses (e.g., accelerations parallel to the z-axis).

Proof masses 102 and 104 may be connected to an underlying substrate 101 (shown in FIG. 1C) via anchors 132 and 134, respectively. In some embodiments, proof masses 102 and 104 are connected to the respective anchors via a plurality of tethers. One such configuration is illustrated in FIG. 1B. As illustrated, tethers 130 and 131 may be formed by removing (for example, via etching) portions 107 from proof mass 102. Portions 107 may be removed to form an anchored proof mass portion 106 and tethers 130 and 131. The anchored proof mass portion 106 may be connected to anchor 132 (not shown in FIG. 1B), and may be connected to the body of the proof mass 102 via tethers 130 and 131. Tethers 130 and 131 may be configured to torque in the xz-plane in response to accelerations parallel to the z-axis, thereby allowing for rotations of proof mass 102 about anchor 132. In the example illustrated in FIG. 1B, the tethers are configured to torque and they are separated along a direction parallel to the y-axis. Alternatively, or additionally, tethers separated along the x-axis may be used to couple anchored proof mass portion 106 to the body of the proof mass. Instead of torqueing, such tethers may be configured to flex out-of-plane. Of course, the various aspects described herein are not limited to any specific type or number of tethers. Though not illustrated, proof mass 104 may be connected to anchor 134 in a similar arrangement to that shown in FIG. 1B.

Referring back to FIG. 1A, proof mass 102 may have a first mass portion or segment 112 and a second mass portion or segment 114, and proof mass 104 may have a first mass portion or segment 116 and a second mass portion or segment 118. Mass portions 112 and 114 may represent, or be disposed at, opposite sides of proof mass 102, with respect to anchor 132. Mass portions 116 and 118 may represent, or be disposed at, opposite sides of proof mass 104, with respect to anchor 134. As such, proof masses 102 and 104 may operate as teeter-totters. That is, when one end or mass portion moves in one direction out-of-plane, the opposite end or mass portion moves in the opposite direction by allowing the proof mass to pivot about the anchor.

Mass portions 112 and 114 may have different weights. The illustrated embodiment shows, for example, mass portion 112 having a larger surface than that of mass portion 114 (the length L₁ of mass portion 112 being greater than the length L₂ of mass portion 114, at least in some embodiments). As a result, mass portion 112 is heavier than mass portion 114. Similarly, first mass portion 116 may be heavier than second mass portion 118 (the length L₃ of mass portion 116 being greater than the length L₄ of mass portion 118, at least in some embodiments). In some embodiments, proof masses 102 and 104 may comprise mass portions 115 and 117, respectively, although not all embodiments include such mass portions. Mass portions 115 and 117 may extend, in opposite directions, along the y-axis. For example, proof masses 102 and 104 may be L-shaped. In this way, additional surface may be included, thus increasing the sensitivity to accelerations, without substantially increasing space usage on the substrate. In some embodiments, the proof masses are arranged such that mass portion 112 is proximate to mass portion 118 and mass portion 114 is proximate to mass portion 116. Of course, other arrangements are also possible.

In some embodiments, mass portions 112 and 114, and mass portions 116 and 118 may be continuously solid; that is, they may comprise solid, uninterrupted portions of material within the boundaries of the mass portion (except for the removed portions 107 around the anchors as shown in FIG. 1B). As discussed above, MEMS resonant accelerometers of the type described herein may be configured such that the proof mass and the resonator share the same mass (e.g., proof mass 102). That is, the single mass can 1) be driven to oscillate, thus serving as a resonator, when a drive signal is applied to a drive electrode, and 2) serve as a proof mass by detecting its motion using a sense electrode, thus detecting acceleration. As such, mass portions 112, 114, 116 and 118 may lack resonating structures configured to move independently from the proof masses. In some embodiments, the MEMS resonant accelerometer may be arranged such that the resonator (that is, the mass configured to oscillate when driven with a drive signal) is connected to an anchor via tethers.

In some embodiments, the proof masses 102 and 104 may lack structures, such as movable frames, configured to move independently from the proof masses. As used herein, the term “frame” is used to indicate any mass enclosing at least one of the proof masses 102 and 104 in the xy-plane. Of course, MEMS accelerometers of the types described herein may comprise fixed frames enclosing proof masses 102 and 104. One example of a fixed frame is a portion of substrate in which a cavity is formed such that the proof masses are positioned in the cavity.

Proof masses 102 and 104 may be made of a conductor and/or semiconductor material, such as single-crystal silicon or polycrystalline silicon. Drive electrodes 120 and 126 may be disposed on substrate 101, and may form a pair of drive capacitors with proof masses 102 and 104, respectively. As illustrated in FIG. 1C, drive electrodes 120 and 126 may be coupled to drive circuitry 150, which may be disposed on the same substrate as MEMS resonant accelerometer 100, or an a separate substrate. Drive circuitry 150 may be configured to excite the drive capacitors with alternating current (AC) signals (e.g., periodic signals), thereby causing the proof masses to pivot about the anchors, and as a result, to oscillate (via electrostatic attraction/repulsion) out-of-plane.

Sense electrodes 122 and 124 may form a pair of sense capacitors with proof masses 102 and 104, respectively. When proof masses 102 and 104 move out-of-plane, the sense capacitors experience a variation in capacitance, due to a change in the separation between the proof mass and the sense electrodes. As such, the sense capacitors may detect motion of the proof masses (whether this motion is caused by accelerations experienced by the proof mass, by drive signals, or by other reasons). In some embodiments, sense circuitry 152, which is coupled to sense electrodes 120 and 122, may be configured to detect the frequenc(ies) with which proof masses 102 and 104 oscillate, based on the signals obtained from the sense capacitors.

First, a case in which no accelerations along the z-axis are present is considered. This case is illustrated schematically in the example of FIG. 1D, which is a cross-sectional view. If drive circuitry 150 drives the drive capacitors with a signal oscillating in time at a frequency f, the proof masses may in response oscillate out-of-plane with an oscillation period given by 1/f. As a result, the frequency detected by sense circuitry 152 may be equal to f. As illustrated, the average separation between a reference location X₀ of proof mass 102 and sense electrode 122 is denoted by the letter “s₁”. When a proof mass is still and the separation between the proof mass and the sense electrode 122 is equal to s₁, the proof mass is said to be in its “resting position”. It should be appreciated that, since the anchor is offset from its center of mass, the proof mass may not be horizontal (parallel to the xy-plane) in the resting position. The oscillating signal provided by drive circuitry 150 causes proof mass 102 to oscillate about the resting position. Separation s₁ may be less than 1 μm, less than 800 nm, less than 600 nm, less than 400 nm, less than 200 nm or less than 100 nm, as non-limiting example.

Second, a case in which MEMS resonant accelerometer 100 experiences an acceleration a_{z} directed along the z-axis is considered. This case is illustrated schematically in the example of FIG. 1E. Furthermore, it is assumed that no drive signals are applied to the drive capacitors. In this case, due to the fact the proof masses 102 and 104 are anchored away from their centers of mass, a net non-zero force is applied to the center of the masses. As a result, the proof masses may rotate about the respective anchors thus departing from their resting positions. For example, in cases in which a_{z} is directed from the upper portion of FIG. 1C to the lower portion of FIG. 1C, as shown by vector 160, proof masses 102 and 104 rotate about the anchors such that the separation between the heavy mass portions and the substrate is reduced. In this case, the separation between reference location X₀ of proof mass 102 and sense electrode 122 is denoted by “s₂”. Displacement of the proof masses may be detected by the sense electrodes.

Finally, a case in which a drive signal and a z-axis acceleration are present is considered. This case is illustrated schematically in the example of FIG. 1F. As in the case illustrated in FIG. 1D, the drive signals, which oscillate at frequency f, cause the proof masses to oscillate out-of-plane. However, due to the presence of the z-axis acceleration a_{z}, the average separation between reference location X₀ and sense electrode 122 is s₂, rather than s₁. As a result, the effective stiffness of the proof masses may vary, and such variations may cause shifts in the proof masses' resonant frequencies. The extent to which the resonant frequencies shifts from frequency f may depend on the magnitude of acceleration a_{z}. Therefore, in some embodiments, sense circuitry 152 may infer the magnitude of the acceleration based on the shift in the resonant frequencies.

According to one aspect of the present application, differential signals may be generated in response to accelerations parallel to the z-axis. Compared to single-ended signals, differential signals may be more immune to common mode signals, such as undesired signals caused by deformations of the substrate due to stress. To generate differential signals, in some embodiments, sense electrode 122 may be positioned in proximity to mass portion 114 (e.g., such that mass portion 114 and sense electrode 122 spatially overlap, at least in part, in the xy-plane while being separated along the z-axis), and sense electrode 124 may be positioned in proximity to mass portion 116. This configuration is illustrated in FIG. 1A. In this way, when the separation between proof mass 102 and sense electrode 122 increases, the separation between proof mass 104 and sense electrode 124 decreases (and vice versa). As a result, when the frequency of the signal sensed by sense electrode 122 increases, with respect to the frequency of the driving signal, the frequency of the signal sensed by sense electrode 124 decreases, and differential signals may be generated. In some embodiments, proof masses 102 and 104 may be driven to resonate out-of-phase with respect to each other (e.g., with a phase difference that is 180°, or between 170° and 190°).

In one example, assuming that the frequency of the driving signal is f, the frequency of the signal sensed by sense electrode 122 in the presence of a z-axis acceleration may be f₁=f+Δf₁ and the frequency of the signal sensed by sense electrode 124 may be f₂=f−Δf₂. Sense circuitry 152 may be configured to compute f₁-f₂, thus obtaining Δf₁+Δf₂. The magnitude of the acceleration may be inferred from Δf₁+ΔM₂. Being a differential detection, common mode signals captured by both sense electrodes 122 and 124 (such as signals caused by deformations of the substrate due to stress) may be rejected (or at least limited). In some embodiments, the sense electrodes may be positioned such that, in the presence of z-axis accelerations, Δf₁=Δf₂=Δf. In these embodiments, f₁-f₂=2Δf.

As seen in FIGS. 1A-1F, in some embodiments, sense electrode 122 and drive electrode 120 are positioned in proximity to the same portion of proof mass 102. That is, sense electrode 122 and drive electrode 120 may be positioned on the same side of proof mass 102, along the x-axis, with respect to anchor 132. Similarly, sense electrode 124 and drive electrode 126 may be positioned in proximity to the same portion of proof mass 104. In some embodiments, positioning the sense electrode and the drive electrode between a common mass portion of a proof mass and the substrate (i.e., on the same side of the proof mass with respect to the anchor location) may ensure that that when the separation between the proof mass and the drive electrode increases, the separation between the proof mass and the sense electrode also increases, thus enhancing the response of the accelerometer.

In some embodiments, the sense electrodes are positioned such that one sense electrode is proximate the heavy mass portion of a proof mass and the other sense electrode is proximate the light mass portion of the other proof mass. For example, FIG. 1A illustrates a case in which sense electrode 122 is proximate the mass portion 114 (which is the lighter mass portion in some embodiments) of proof mass 102, and sense electrode 124 is proximate the mass portion 116 (which is the heavier mass portion in some embodiments) of proof mass 104. This configuration may ensure that when the separation between one proof mass and its corresponding sense electrode increases, the separation between the other proof mass and its corresponding sense electrode decreases. As a result, differential signals may be generated in response to accelerations, and undesired signals (e.g., signal offsets caused by stress in the substrate or sense signals arising from accelerations that are not parallel to the z-axis) may be rejected or at least limited.

In the embodiment illustrated in FIG. 1A, proof masses 102 and 104 are generally elongated in a direction parallel to the x-axis. In some embodiments, anchors 132 and 134 are aligned along the x-axis such that proof mass 102 and proof mass 104 share the same rotation axis 140. Sharing the same rotation axis may be desirable as undesired signals, generated for example due to stress in the substrate, may be equally sensed by the two proof masses and therefore may be rejected as common modes. Of course, the application is not limited in this respect as the anchors 132 and 134 may be substantially aligned along the x-axis in some embodiments. That is, anchors 132 and 134 may be partially offset from one another (e.g., by less than 100 nm, less than 250 nm, less than 500 nm, less than 1 μm, less than 1 μm, less than 5 μm, or less than 10 μm) along the x-axis.

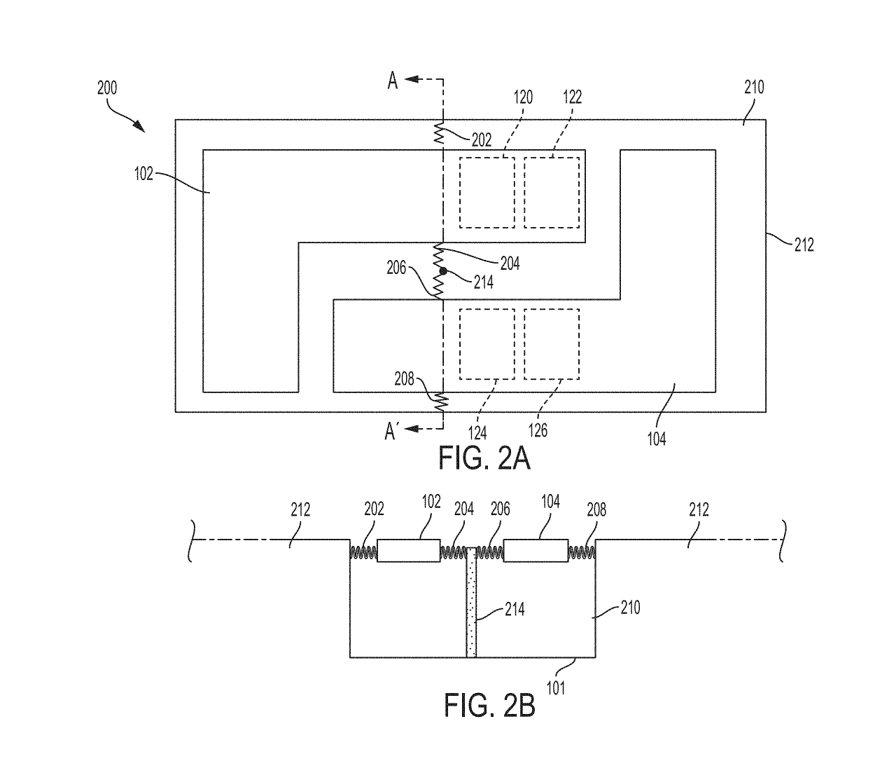

In the embodiments described in connection with FIGS. 1A-1F, proof masses 102 and 104 are connected to substrate 101 via anchors 132 and 134. However, the application is not limited in this respect as other ways of connecting the proof masses to the substrate may be used. For example, the proof masses may be connected to the substrate through a plurality of hinges. One such configuration is illustrated in FIGS. 2A-2B, where FIG. 2B is a cross sectional view of the top view of FIG. 2A taken along line AA′. As in the embodiments described above, MEMS resonant accelerometer 200 comprises proof masses 102 and 104, sense electrodes 122 and 124, and drive electrodes 120 and 126. In this case, however, proof mass 102 is connected to substrate 101 via hinges 202 and 204, and proof mass 104 is connected to substrate 101 via hinges 206 and 208. MEMS resonant accelerometer 200 may be formed in an opening 210 in the substrate. Specifically, as illustrated in FIG. 2B, opening 210 may be formed in the raised portion 212 of substrate 101.

In some embodiments, hinge 202 may connect proof mass 102 to raised portion 212 and hinge 204 may connect proof mass 102 to anchor 214. Similarly, hinge 208 may connect proof mass 104 to raised portion 212 and hinge 206 may connect proof mass 104 to anchor 214 (or alternatively, to a separate anchor). In other embodiments, hinges 204 and 206 are connected to a raised portion of the substrate (e.g., a raised portion formed in the opening 210). The hinges may allow motion of the proof masses out of the xy-plane in response to drive signals and to z-axis accelerations. Accordingly, MEMS resonant accelerometer 200 may operate in the same manner described in connection with MEMS resonant accelerometer 100.

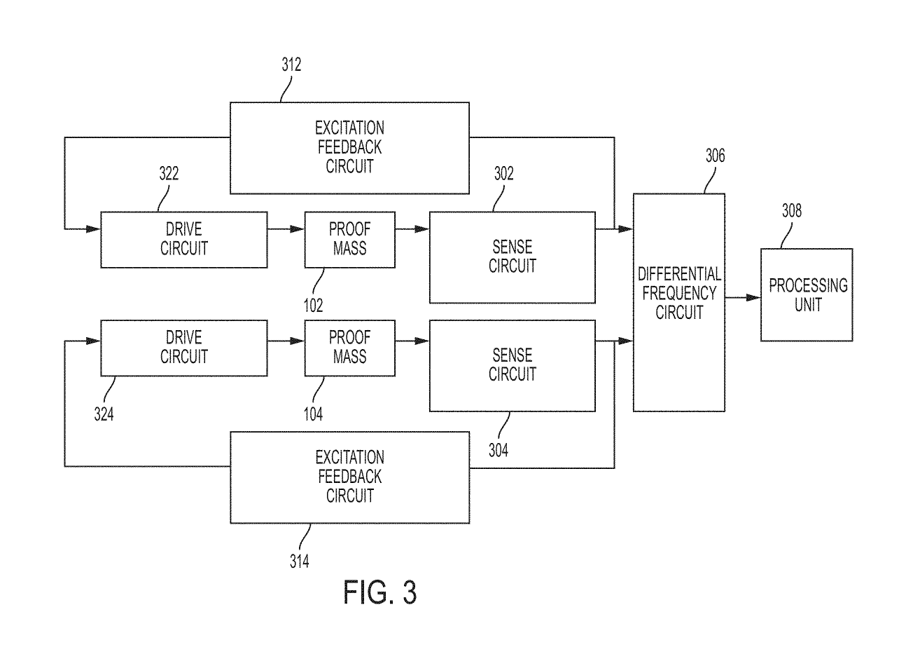

As described above, drive circuitry 150 may be configured to provide drive signals to the drive capacitors and sense circuitry 152 may be configured to detect signals provided by the sense capacitors, and to detect variations in resonant frequency with respect to the frequency of the drive signals. A non-limiting implementation of drive circuitry 150 and sense circuitry 152 is shown in FIG. 3. System 300 may comprise proof masses 102 and 104 (arranged in any one of the configurations described above) sense circuits 302 and 304, excitation feedback circuits 312 and 314, drive circuits 322 and 324, differential frequency circuit 306 and processing unit 308.

Sense circuit 302 may be coupled to sense electrode 122 and sense circuit 304 may be coupled to sense electrode 124. Sense circuits 302 and 304 may collectively serve as sense circuitry 152. Drive circuit 322 may be coupled to drive electrode 120 and drive circuit 324 may be coupled to drive electrode 126. Drive circuits 322 and 324 may collectively serve as drive circuitry 150. Sense circuits 302 and 304 may be configured to receive signals generated in response to motion of the proof masses, and to obtain the frequencies at which the signals resonate. As described above, the frequencies at which these signals resonate may be different, depending on the magnitude of the acceleration experienced by the proof masses, from the resonant frequency of the drive signals. In some embodiments, sense circuits 302 and 304 may each comprise a phase-locked loop (PLL). The PLLs may be configured to lock to the frequencies at which the received signals resonate, and to output values representative of these frequencies.

Differential frequency circuit 306 may be configured to combine the frequencies obtained with sense circuits 306. This may be performed in the analog and/or the digital domain. As such, sense circuits 302 and 304 may comprise analog-to-digital converters in some embodiments. In some embodiments, differential frequency circuit 306 subtracts the frequency obtained with sense circuit 302 from the frequency obtained with sense circuit 304 (or vice versa), thus obtaining a differential representation of the acceleration experienced by the MEMS resonant accelerometer. The result of this operation may be, for example, Δf₁+Δf₂ or 2Δf. Processing unit 308 may infer the magnitude of the acceleration based on such a differential representation. For example, processing unit 308 may include a memory loaded with a look-up-table (LUT) mapping acceleration magnitude to Δf₁+Δf₂ (or 2Δf). The LUT may be generated, for example, using a calibration procedure.

In some embodiments, the proof masses may be driven based on the frequencies sensed by the sense circuits. As such, feedback loop circuits may be provided. In the example of FIG. 3, excitation feedback circuit 312 couples sense circuit 302 to drive circuit 322 and excitation feedback circuit 314 couples sense circuit 304 to drive circuit 324. The excitation feedback circuits may be configured to cause the drive circuits to select the driving frequencies based on the sensed frequencies. This may be done, for example, to ensure that the proof masses do not oscillate outside a motion range deemed safe. Drive circuits 322 and 324 may each comprise an oscillator configured to output a periodic signal (e.g., a sinusoidal signal). In some embodiments, the signals provided by drive circuits 322 and 324 may be out-of-phase with respect to one another (e.g., with a phase difference of 180° or between 170° and 190°).

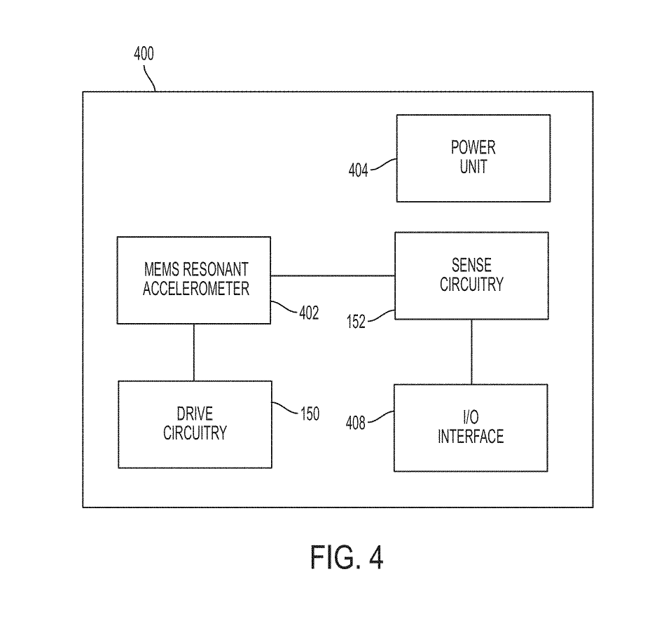

MEMS resonant accelerometers of the type described herein may be used in connection with other electrical components to form electronic systems. An example of such an electronic system is depicted in FIG. 4. System 400 may be deployed in various settings to detect acceleration, including sports, healthcare, military, and industrial applications, among others. For example, a system 400 may be a wearable sensor deployed in monitoring sports-related physical activity and performance, patient health, military personnel activity, or other applications of interest of a user. In another example, a system 400 may be used in seismic applications, such as to sense and/or predict earthquakes.

System 400 may comprise MEMS resonant accelerometer 402, drive circuitry 150, sense circuitry 152, I/O interface 408, and power unit 404. MEMS resonant accelerometer 402 may be implemented using any one of the embodiments described above. Drive circuitry 150 and sense circuitry 152 have been described above.

System 400 may periodically transmit, via wired connections or wirelessly, signals representative of sensed accelerations to an external monitoring system, such as a computer, a smartphone, a tablet, a smartwatch, smartglasses, or any other suitable receiving device. I/O interface 408 may be configured to transmit and/or receive data via Wi-Fi, Bluetooth, Bluetooth Low Energy (BLE), Zigbee, Thread, ANT, ANT+, IEEE 802.15.4, IEEE 802.11.ah, or any other suitable wireless communication protocol. Alternatively, or additionally, I/O interface 408 may be configured to transmit and/or receive data using proprietary connectivity protocols. I/O interface 408 may comprise one or more antennas, such as a microstrip antenna. In some embodiments, I/O interface 408 may be connected to a cable, and may be configured to transmit and/or receive signals through the cable.

System 400 may be powered using power unit 404. Power unit may be configured to power drive circuitry 150, sense circuitry 152, and I/O interface 408, or just a subset of these. In some embodiments, power unit 404 may comprise one or more batteries. System 400 may, in at least some embodiments, consume sufficiently little power to allow for its operation for extended periods based solely on battery power. The battery or batteries may be rechargeable in some embodiments. Power unit 404 may comprise one or more lithium-ion batteries, lithium polymer (LiPo) batteries, super-capacitor-based batteries, alkaline batteries, aluminum-ion batteries, mercury batteries, dry-cell batteries, zinc-carbon batteries, nickel-cadmium batteries, graphene batteries or any other suitable type of battery. In some embodiments, power unit 404 may comprise circuitry to convert AC power to DC power. For example, power unit 404 may receive AC power from a power source external to system 400, such as via I/O interface 408, and may provide DC power to some or all the components of system 400. In such instances, power unit 404 may comprise a rectifier, a voltage regulator, a DC-DC converter, or any other suitable apparatus for power conversion.

Power unit 404 may comprise energy harvesting components and/or energy storage components, in some embodiments. Energy may be harvested from the surrounding environment and stored for powering the system 400 when needed, which may include periodic, random, or continuous powering. The type of energy harvesting components implemented may be selected based on the anticipated environment of the system 400, for example based on the expected magnitude and frequency of motion the system 400 is likely to experience, the amount of stress the system is likely to experience, the amount of light exposure the system is likely to experience, and/or the temperature(s) to which the system is likely to be exposed, among other possible considerations. Examples of suitable energy harvesting technologies include thermoelectric energy harvesting, magnetic vibrational harvesting, electrical overstress harvesting, photovoltaic harvesting, radio frequency harvesting, and kinetic energy harvesting. The energy storage components may comprise supercapacitors in some embodiments.

In some embodiments, system 400 may comprise one or more other MEMS devices, such as gyroscopes, resonators, and/or other types of accelerometers. The MEMS devices may be used collectively to analyze the overall behavior of a person or an object, on which system 400 is disposed.

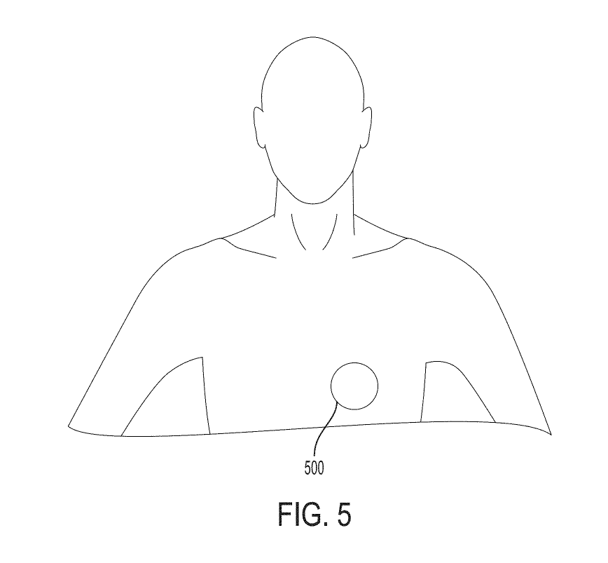

One representative application of system 400 is in health monitoring devices, as depicted in FIG. 5. Device 500, which may comprise system 400, may be configured to be attached, tied or clipped to the body of a user. In some embodiments, device 500 may be configured to detect accelerations caused by the user's cardiovascular activity and/or pulmonary activity. Additionally, or alternatively, device 500 may be configured to monitor a user's physical activity, for example by counting the number of steps, by measuring stride length, and/or by measuring a limb's motion range. Device 500 is not limited to being connected to a user's chest, as illustrated in FIG. 5, and may be connected to any other suitable part of a user's body.

Aspects of the present application may provide one or more benefits, some of which have been previously described. Now described are some non-limiting examples of such benefits. It should be appreciated that not all aspects and embodiments necessarily provide all of the benefits now described. Further, it should be appreciated that aspects of the present application may provide additional benefits to those now described.

Aspects of the present application provide MEMS resonant accelerometers having increased sensitivity to accelerations. This may be particularly beneficial in applications that call for the ability to detect weak accelerations. Aspects of the present application provide MEMS resonant accelerometers, that, compared to conventional MEMS resonant accelerometers, have a reduced space usage, thus making them more compact and cost efficient.

1. A microelectromechanical system (MEMS) resonant accelerometer comprising:
a first teeter-totter proof mass coupled to a substrate through a first anchor at a first anchor location, the first teeter-totter proof mass having first and second mass portions disposed on opposite sides of the first anchor location, wherein the first mass portion is heavier than the second mass portion;
a second teeter-totter proof mass coupled to the substrate through a second anchor at a second anchor location, the second teeter-totter proof mass having first and second mass portions disposed on opposite sides of the second anchor location, wherein the first mass portion is heavier than the second mass portion;
a first sense electrode and a first drive electrode disposed between a common mass portion of the first teeter-totter proof mass and the substrate; and
a second sense electrode and a second drive electrode disposed between a common mass portion of the second teeter-totter proof mass and the substrate.

2. The MEMS resonant accelerometer of claim 1, wherein the common mass portion of the first teeter-totter proof mass is the first mass portion of the first teeter-totter proof mass and the common mass portion of the second teeter-totter proof mass is the second mass portion of the second teeter-totter proof mass.

3. The MEMS resonant accelerometer of claim 1, wherein the first and second mass portions of the first teeter-totter proof mass lack structures configured to move independently from the first and second mass portions of the first teeter-totter proof mass.

4. The MEMS resonant accelerometer of claim 1, wherein the first and second mass portions of the first teeter-totter proof mass form a continuously solid mass.

5. The MEMS resonant accelerometer of claim 1, further comprising drive circuitry configured to provide a first periodic drive signal to the first drive electrode and to provide a second periodic drive signal to the second drive electrode.

6. The MEMS resonant accelerometer of claim 5, wherein the first and second periodic drive signals are out-of-phase with respect to each other.

7. The MEMS resonant accelerometer of claim 1, further comprising sense circuitry configured to receive a first sense signal from the first sense electrode and a second sense signal from the second sense electrode, and to compute a differential resonant frequency based on the first and second sense signals.

8. The MEMS resonant accelerometer of claim 1, wherein the first and second mass portions of the first teeter-totter proof mass are offset from one another along a first direction, and wherein the first anchor and the second anchor are substantially aligned along a second direction perpendicular to the first direction.

9. The MEMS resonant accelerometer of claim 1, wherein the first mass portion of the first teeter-totter proof mass is in proximity to the second mass portion of the second teeter-totter proof mass, and the second mass portion of the first teeter-totter proof mass is in proximity to the first mass portion of the second teeter-totter proof mass.

10. The MEMS resonant accelerometer of claim 1, wherein the first anchor is coupled to the first teeter-totter proof mass through a plurality of tethers.

11. The MEMS resonant accelerometer of claim 1, wherein the teeter-totter proof masses are separated from the substrate by less than 1 μm.

12. A microelectromechanical system (MEMS) resonant accelerometer comprising:
a pair of teeter-totter proof masses coupled to a substrate via respective anchors, each one of the anchors being offset with respect to a center of mass of the respective teeter-totter proof mass, wherein each of the anchors separates the respective teeter-totter proof mass into a first mass portion and a second mass portion, wherein the first mass portion is heavier than the second mass portion;
a first sense electrode and a first drive electrode disposed between the first mass portion of a first teeter-totter proof mass of the pair of teeter-totter proof masses and the substrate; and
a second sense electrode and a second drive electrode disposed between the second mass portion of a second teeter-totter proof mass of the pair of teeter-totter proof masses and the substrate.

13. The MEMS resonant accelerometer of claim 12, wherein the first teeter-totter proof mass lacks structures configured to move independently from the first teeter-totter proof mass.

14. The MEMS resonant accelerometer of claim 12, wherein the first and second mass portions are continuously solid.

15. The MEMS resonant accelerometer of claim 12, wherein each of the pair of teeter-totter proof masses is separated from the substrate by less than 1 μm.

16. The MEMS resonant accelerometer of claim 12, further comprising drive circuitry configured to provide periodic drive signals to the first and second drive electrodes that are out-of-phase with respect to each other.

17. A method for sensing accelerations using a MEMS resonant accelerometer, the method comprising:
causing a first teeter-totter proof mass coupled to a substrate via a first anchor disposed at a first anchor location offset from a center of mass of the first teeter-totter proof mass and comprising first and second mass portions disposed on opposite sides of the first anchor location to resonate out-of-plane by applying a first drive signal to a first drive electrode disposed between a first mass portion of the first teeter-totter proof mass and the substrate;
causing a second teeter-totter proof mass coupled to the substrate via a second anchor disposed at a second anchor location offset from a center of mass of the second teeter-totter proof mass and comprising first and second mass portions disposed on opposite sides of the second anchor location to resonate out-of-plane by applying a second drive signal to a second drive electrode disposed between a second mass portion of the second teeter-totter proof mass and the substrate;
sensing motion of the first teeter-totter proof mass by sensing a first sense signal produced by a first sense electrode disposed between the first mass portion of the first teeter-totter proof mass and the substrate; and
sensing motion of the second teeter-totter proof mass by sensing a second sense signal produced by a second sense electrode disposed between the second mass portion of the second teeter-totter proof mass and the substrate.

18. The method of claim 17, further comprising obtaining a first resonant frequency based on the first sense signals and a second resonant frequency based on the second sense signal.

19. The method of claim 17, further comprising obtaining information indicative of an acceleration based on the first and second resonant frequencies.

20. The method of claim 17, wherein the first and second drive signals are out-of-phase with respect to each other.
